(19) United States
(12) Patent Application Publication
(10) Pub. No.: US 2009/0295770 A1
(43) Pub. Date: Dec. 3, 2009

(54) LEVEL SHIFTER USING LATCH CIRCUIT AND DRIVING CIRCUIT INCLUDING THE SAME IN DISPLAY DEVICE

(75) Inventors: Jae Hyuck WOO, Osan-si (KR); Jae Goo LEE, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/468,115

(22) Filed: May 19, 2009

(30) Foreign Application Priority Data
May 27, 2008 (KR) 2008-49173

(51) Int. Cl. G09G 5/00; H03K 19/0175

(52) U.S. Cl. 345/208; 326/80

(57) ABSTRACT

A level shifter includes a switching unit, a power supply circuit, and a latch circuit. The switching unit selectively outputs an input signal to a first output terminal in response to a first control signal. The power supply circuit generates a variable voltage, which changes when level shifting is performed, in response to a plurality of second control signals. The latch circuit performs the level shifting in response to the input signal selectively output by the switching unit and the variable voltage. Since the level shifter can perform level shifting using the latch circuit, it can be made in compact size and it operates with low power. Also, the level shifter sets the transition periods of the first control signal and the variable voltage not to overlap each other, thereby decreasing signal distortion.

### CROSS-REFERENCE TO RELATED APPLICATIONS

This application claims priority under 35 U.S.C. §119 from Korean Patent Application No. 10-2008-0049173, filed on May 27, 2008, in the Korean Intellectual Property Office, the disclosure of which is incorporated herein by reference.

### BACKGROUND

1. Field of the Invention

The present general inventive concept relates to level shifting technology, and more particularly, to a level shifter to perform level shifting using a latch circuit driven in response to a variable voltage and a driving circuit including the same in a display device.

2. Description of the Related Art

A level shifter is usually used to raise the voltage level of a signal to a predetermined voltage level in various digital circuits. A typical level shifter includes a pair of transistors receiving differential input signals and a load terminal having a diode structure. The transistors in the pair are larger (e.g., 12 times larger) in size than a transistor in the load terminal in order to perform reliable level shifting even at a low voltage. The large size of the transistors increases the size of the level shifter.

Another drawback can be that since a voltage drop occurs according to the diode structure of the load terminal, an output voltage of the level shifter may become lower than a power supply voltage and the current driving performance of the level shifter may be limited. As a result, the diode structure of the load terminal may increase the power consumption of the level shifter.

### SUMMARY

Embodiments of the present general inventive concept provide a level shifter having a compact size and a low-power characteristic and a driving circuit including the same in a display device.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a level shifter including a switching unit, a power supply circuit, and a latch circuit. The switching unit selectively outputs an input signal to a first output terminal in response to a first control signal. The power supply circuit generates a variable voltage signal, which changes when level shifting is performed, in response to a plurality of second control signals. The latch circuit performs the level shifting in response to the input signals selectively output by the switching unit and the variable voltage signal. Transition periods of the first control signal and the variable voltage signal may be set not to overlap each other to decrease the distortion of an output signal.

The latch circuit may include a pair of inverters connected in parallel between the first output terminal and a second output terminal in opposite directions. Driving voltage of the respective inverters may be the variable voltage and a third voltage, respectively. The third voltage may be a ground voltage.

The power supply circuit may include a plurality of voltage input terminals configured to respectively receive voltages having different levels and a plurality of switches each configured to selectively connect a corresponding terminal among the plurality of voltage input terminals to a variable voltage output terminal in response to a corresponding signal among the plurality of second control signals. At this time, transition periods of the second control signals do not overlap each other.

The plurality of switches may include a plurality of first switches connected in series between a first input terminal receiving a first voltage and the variable voltage output terminal to operate in response to a corresponding signal among the plurality of second control signals and at least one second switch connected between a second input terminal receiving a second voltage and the variable voltage output terminal to operate in response to a corresponding signal among the plurality of second control signals.

The power supply circuit may further include a discharge circuit connected between a ground voltage line and a first node between a first input terminal and the variable voltage output terminal. The discharge circuit may decrease a voltage of the first node down to a predetermined voltage level in response to a third control signal while the variable voltage signal transitions from a second level higher than a first level to the first level. The discharge circuit may include a control element connected between the first node and a second node to determine whether to drive the discharge circuit in response to the third control signal and at least one transistor connected between the second node and the ground voltage line in diode connection.

The power supply circuit may further include a stabilizing circuit connected between the variable voltage output terminal and the ground voltage line to prevent rapid change of the variable voltage. The stabilizing circuit may include a capacitor connected between the variable voltage output terminal and the ground voltage line.

The foregoing and/or other aspects and utilities of the present general inventive concept may also be achieved by providing a driving circuit in a display device. The driving circuit includes a level shifter, a digital-to-analog converter, and an analog buffer. The level shifter receives digital data and performs level shifting on the digital data. The technological features of the level shifter have been described above. Thus, detailed descriptions thereof will be omitted. The digital-to-analog converter receives level-shifted digital data and converts the level-shifted digital data into an analog voltage. The analog buffer buffers the analog voltage to a display panel.

The foregoing and/or other aspects and utilities of the present general inventive concept may also be achieved by providing a display device including a display unit, a level shifter configured to receive digital data and perform level shifting on the digital data, and to output the level shifted data to the display unit such that the display unit displays an image according to the level shifted data, wherein the level shifter includes a switching unit configured to selectively output an input signal to a first output terminal in response to a first control signal, a power supply circuit configured to generate a variable voltage signal, which changes when level shifting is performed, in response to a plurality of second control signals, and a latch circuit configured to perform the level shifting in response to input signals selectively output by the switching unit and the variable voltage signal, wherein transition periods of the first control signal and the variable voltage signal do not overlap each other.

The foregoing and/or other aspects and utilities of the present general inventive concept may also be achieved by providing level shifter in a display device including a switching unit to selectively transmit an input signal according to a first control signal, and a latch circuit unit to adjust a level of the input signal according to a variable voltage signal, wherein transition periods of the first control signal and the variable voltage signal do not overlap.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a circuit diagram illustrating a level shifter according to embodiments of the present general inventive concept;

FIG. 2 is a circuit diagram illustrating a power supply circuit included in the level shifter illustrated in FIG. 1;

FIG. 3 is a timing chart illustrating the operation of the power supply circuit illustrated in FIG. 2;

FIG. 4 is a circuit diagram illustrating an inverter illustrated in FIG. 1;

FIG. 5 is a timing chart illustrating the operation of the level shifter in FIG. 1;

FIG. 6 is a circuit diagram illustrating a level shifter provided for comparison with a level shifter according to embodiments of the present general inventive concept;

FIG. 7 is a graph illustrating an input signal of a level shifter according to embodiments of the present general inventive concept;

FIG. 8A is a graph illustrating a voltage at a first output terminal of the level shifter illustrated in FIG. 6;

FIG. 8B is a graph of a voltage at a first output terminal of a level shifter according to embodiments of the present general inventive concept;

FIG. 9A is a graph illustrating a current supplied from a power supply of the level shifter in FIG. 6;

FIG. 9B is a graph illustrating a current supplied from a power supply circuit of a level shifter according to embodiments of the present general inventive concept; and

FIG. 10 is a block diagram illustrating a driving circuit of a display device according to embodiments of the present general inventive concept.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as “transmitting” data or a signal to another element, it can directly transmit the data or the signal to the other element or at least one intervening element may be present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the present general inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this present general inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

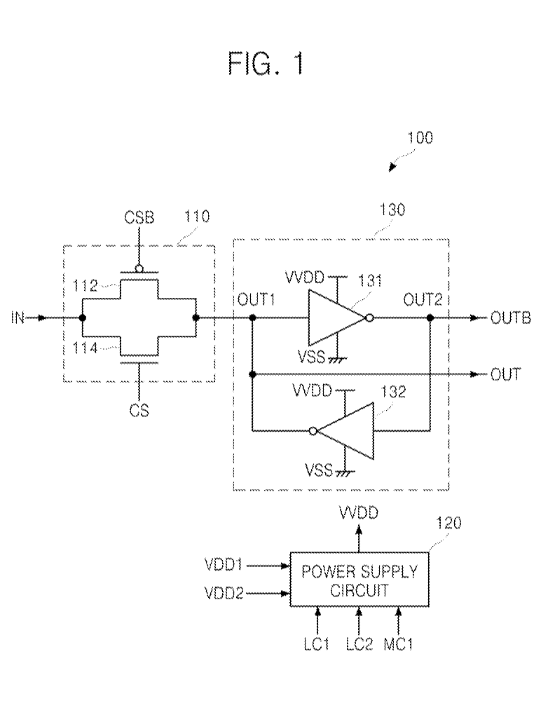

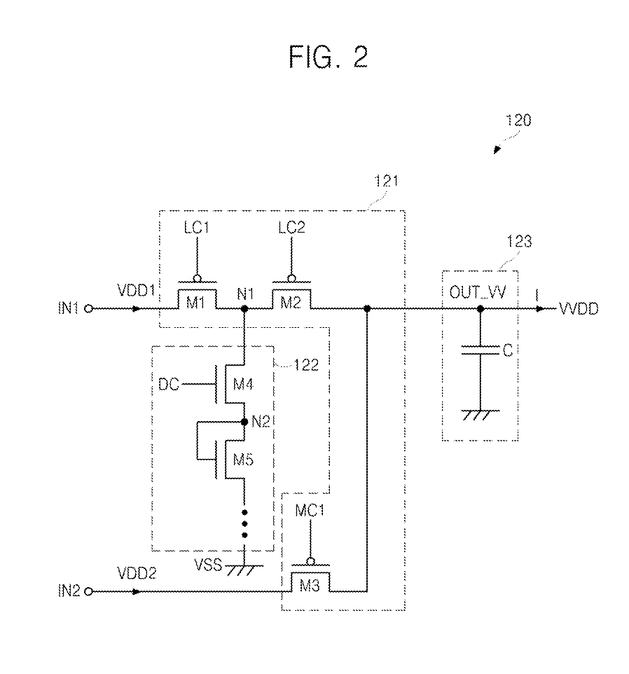

FIG. 1 is a circuit diagram of a level shifter 100 and power supply 120 according to embodiments of the present general inventive concept. FIG. 2 further illustrates a circuit diagram of the power supply circuit 120 included in the level shifter 100 illustrated in FIG. 1. Referring to FIG. 1, the level shifter 100 includes a switching unit 110, the power supply circuit 120, and a latch circuit 130.

The switching unit 110 may selectively output an input signal IN to a first output terminal OUT1 in response to a first control signal CS. The switching unit 110 is implemented by a transmission gate including an N-type metal-oxide semiconductor (NMOS) transistor 114 and a P-type metal-oxide semiconductor (PMOS) transistor 112 which may be driven in response to the first control signal CS at a high level, and a first complementary control signal CSB at a low level, respectively, in the embodiments illustrated in FIG. 1, but the present general inventive concept is not restricted to such a configuration. For example, the switching unit 110 may selectively output the input signal IN to the first output terminal OUT1 only when the first control signal CS is at a high level, regardless of the signal of CSB. Depending on the applications of the level shifter circuit 100, the input signal IN can be transmitted by several logic variations as a result of the signals triggered at CS and CSB, including a reversal of the high and low trigger signals.

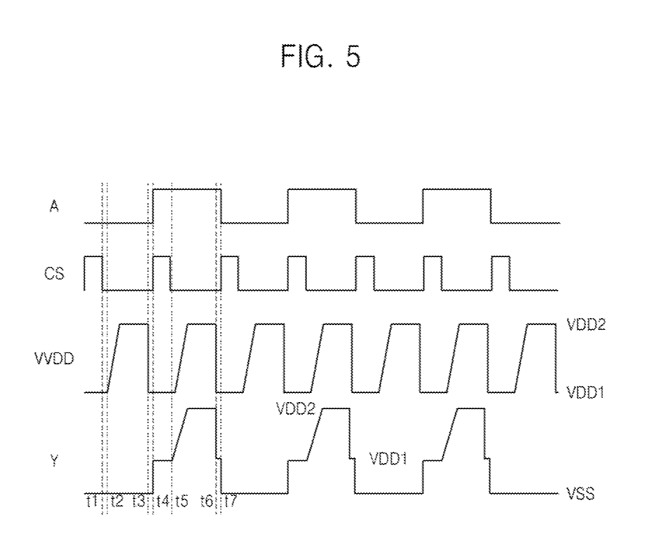

The power supply circuit 120 may generate a variable voltage VVDD whose level changes when level shifting is performed in response to a plurality of second control signals LC1, LC2, and MC1. The changing timing of the variable voltage VVDD will be described with reference to FIG. 5. The power supply circuit 120 illustrated in FIG. 2 may include a plurality of voltage input terminals IN1 and IN2, a switch circuit including a plurality of switches M1, M2, and M3, a discharge circuit 122, and a stabilizing circuit 123.

Among the plurality of voltage input terminals, a first input terminal IN1 receives a first voltage VDD1 and a second input terminal IN2 receives a second voltage VDD2. The level of the second voltage VDD2 may be higher than that of the first voltage VDD1.

Each of the switches M1, M2, and M3 may selectively connect one of the input terminals IN1 and IN2 to a variable voltage output terminal OUT_VV in response to a corresponding signal among the second control signals LC1, LC2, and MC1. The switches M1, M2 and M3 may be NMOS or PMOS transistors. For exemplary purposes, FIG. 2 illustrates the switches M1, M2 and M3 as PMOS transistors, turning “on” when LC1, LC2 and MC1 are at low logic levels. When the transition periods of the second control signals LC1, LC2, and MC1 are set not to overlap one another, a time margin can be secured for the transition of the variable voltage VVDD that changes according to the operations of the switches M1, M2, and M3. Since the switches M1, M2 and M3 do not switch at the same time, but rather overlap in time, a current path to a ground voltage line is prevented from being formed in the switch circuit 121 before a signal may be transmitted to the level shifter 100. This operation of the power supply circuit 120 is in a standby mode, in which the level shifter 100 is provided with only voltage at a first logic level (e.g., the first voltage VDD1) before performing level shifting.

For instance, a high level voltage (e.g., the second voltage VDD2) may be a ground voltage in the standby mode when the transition periods of the second control signals LC1, LC2, and MC1 may overlap, with one or more transistors switching at the same time. When this happens, it is assumed that a current path is formed between the first input terminal IN1 and the second input terminal IN2. In that case, the first voltage VDD1 cannot be stably supplied to the level shifter 100, and therefore, the level shifter 100 may operate erroneously and may be even damaged by a surge current. These problems can be solved by setting the transition periods of the second control signals LC1, LC2, and MC1 different from one another. When the transition periods of the second control signals are set different from one another, the circuit is in an operation mode, and may correctly transfer power signals to the latch circuit 130.

In an exemplary embodiment, the VDD1 voltage signal input through input terminal IN1 may be a low signal of relatively constant voltage, and the VDD2 voltage signal input through input terminal IN2 may be a high signal of relatively constant voltage. However, either or both signals may be the opposite of the exemplary configuration, or either signal may be a mid-range voltage signal, depending on the parameters of the display device other voltage levels of circuits connected to the level shifter.

The discharge circuit 122 may be connected between a node N1 and a ground voltage line VSS. The first node N1 is further positioned between the first input terminal IN1, first switch M1 receiving the first voltage VDD1, and second switch M2 and the variable voltage output terminal OUT_VV. The discharge circuit 122 may drop a voltage at the first node N1 down to a predetermined voltage level in response to a third control signal DC while the variable voltage VVDD transitions downward from a second level higher than a first level to the first level. The predetermined voltage may be the first voltage VDD1. The discharge circuit 122 may include a control element M4 connected between the first node N1 and a second node N2 to determine whether to drive the discharge circuit 122 in response to the third control signal DC and at least one transistor M5 connected between the second node N2 and the ground voltage line VSS in diode connection.

The number of the at least one transistors M5 configured in diode connection may be increased to a number of transistors desired to prevent the transistor M4 from being “always on” in response to the signal from the third control signal DC. The value of the third control signal DC may also be varied depending on the number of transistors M5 connected in series.

The control element M4 may be implemented by a transistor determining whether to discharge the first node N1 in response to the third control signal DC. For instance, the control element M4 is implemented by an NMOS transistor that discharges the first node N1 when the third control signal DC is at a high level. The voltage of the first node N1 may be determined by voltage drop between a source and a drain of the transistor M5 in diode connection.

The stabilizing circuit 123 may be connected between the variable voltage output terminal OUT_VV and the ground voltage line VSS and may prevent rapid change of the variable voltage VVDD. The stabilizing circuit 123 may include a capacitor C connected between the variable voltage output terminal OUT_VV and the ground voltage line VSS.

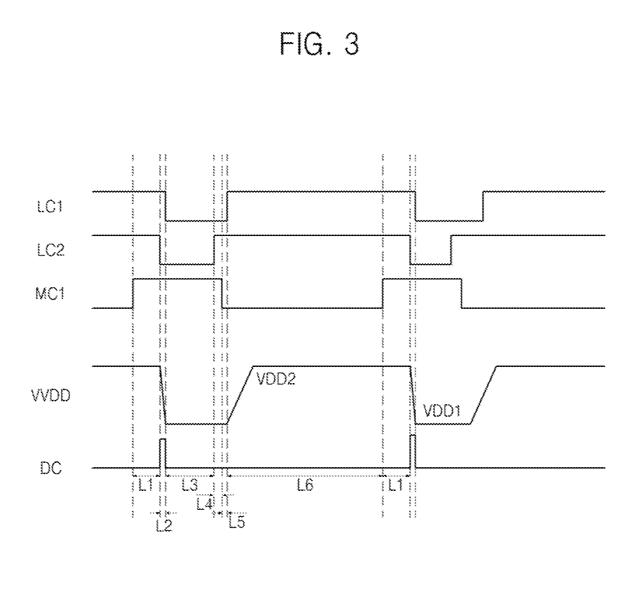

FIG. 3 is a timing chart illustrating the operation of the power supply circuit 120 illustrated in FIG. 2. The operation of the power supply circuit 120 will be sequentially described with reference to FIGS. 2 and 3.

The operation of the power supply circuit 120 to change the variable voltage VVDD from the second voltage VDD2 to the first voltage VDD1 will be described first. The transistor M3 to supply the second voltage VDD2 is initially turned on in response to the low second control signal MC1, and therefore, the variable voltage VVDD becomes the second voltage VDD2 in a period L1. Thus the second voltage VDD2 is output from the stabilizing circuit 123 of the power supply 120 and input to the inverters 131, 132 of the latch circuit 130.

At period L1, switch M3 is triggered from low to high, thus being turned off. The variable voltage VVDD thus remains at VDD2 until further action takes place in the circuit. The transistor M2 connected between the variable voltage output terminal OUT_VV and the first node N1 is turned on in response to the second control signal LC2 triggering from high to low, and the transistor M4 determining whether to discharge the first node N1 is turned on in response to the third control signal DC. The transistor M5 is turned on when transistor M4 is turned on. As a result, the voltage of the first node N1 decreases down to a predetermined voltage level according to the voltage drop of the at least one transistor M5 in diode connection in a period L2. In FIG. 3 the predetermined voltage level may be set to the first voltage VDD1.

The number of transistors M5 determines the voltage drop at node N1. Configured as a diode connection, if the threshold voltage of the transistor M5 is 0.5 volts, for example, a series connection of 10 M5 transistors would require the DC control signal to be greater than 5 volts to allow the switch M2 to operate. Therefore, the variable voltage VVDD would be able to transition downward from the second level VDD2 to the first level VDD1 during the period L2. The width of the pulse DC, and thus the time taken for VDD2 to transition downward to VDD1 may be directly proportional to the number of M5 transistors connected in series.

Thereafter, the transistor M1 to supply the first voltage VDD1 is turned on in response to the second control signal LC1 triggering from high to low. The transistor M2 is also turned on, and therefore, the variable voltage VVDD changes to the first voltage VDD1 in a period L3.

The operation of the power supply circuit 120 changing the variable voltage VVDD from the first voltage VDD1 to the second voltage VDD2 proceeds in reverse order to that in which the variable voltage VVDD changes from the second voltage VDD2 to the first voltage VDD1. In changing the variable voltage VVDD from the first voltage VDD1 to the second voltage VDD2, a sequence of the operations of transistors includes signal LC2 triggering from low to high, thus turning off the transistor M2 in a period L4. During L4 VVDD remains at VDD1. In a period L5, signal MC1 becomes low, thus triggering turn-on of the transistor M3, such that VVDD will take on the value of VDD2. At time L6, signal LC1 changes from low to high, thus triggering turn-off of the transistor M1. The turning off of transistor M1 does not affect the output VVDD, which remains at VDD2. Referring to FIG. 3, at a second period L1, which begins a second cycle, the signal MC1 triggers from low to high, thus turning off the switch M3. Thus, output VVDD will again remain at the level of VDD2 until LC2 again triggers M2 on, which will activate the discharge circuit 122, to begin dropping the voltage VVDD down to the predetermined level. One of the characteristics that allows this operation of the power supply circuit 120 is that the transition periods of the second control signals LC1, LC2, and MC1 do not overlap one another.

The latch circuit 130 may perform level shifting in response to the input signal IN selectively output by the switching unit 110 and the variable voltage VVDD output from the power supply circuit 120. At this time, distortion of output signals OUT and OUTB can be decreased by setting the transition periods of the first control signal CS and the variable voltage VVDD to not overlap each other.

The latch circuit 130 may include a pair of inverters 131 and 132 illustrated in FIG. 1 connected in parallel between the first output terminal OUT1 and a second output terminal OUT2 in opposite directions. The inverters 131 and 132 may have the variable voltage VVDD and a third voltage VSS as their driving voltages, respectively. The third voltage VSS may be a ground voltage. Since the level shifter 100 according to embodiments of the present general inventive concept performs level shifting using the inverters 131 and 132, the level shifter does not need differential input signals, unlike conventional level shifters. Accordingly, the level shifter 100 does not need an inverter to generate a complementary input signal.

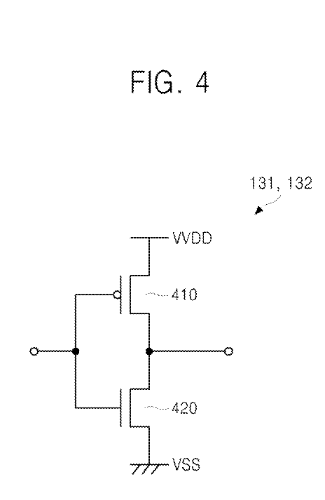

FIG. 4 is a circuit diagram of a CMOS inverter 131 or 132 illustrated in FIG. 1. Referring to FIG. 4, the inverter 131 or 132 may be implemented by a PMOS transistor 410 and an NMOS 420 transistor connected in series between the variable voltage VVDD and the ground voltage VSS. An output voltage of the inverter 131 or 132 may be the ground voltage VSS or the variable voltage VVDD. The level shifter 100 performs level shifting by outputting the variable voltage VVDD having a higher level than a voltage of the input signal IN.

FIG. 5 is a timing chart illustrating the operation of the level shifter 100 illustrated in FIG. 1. The level shifting operation of the level shifter 100 based on a voltage of the first output terminal OUT1 will be described.

In FIG. 5, “A” represents a standard clock pulse, iterating between a “low” and a “high” signal at times “t4,” “t7,” etc. The pulse “CS” represents the first control signal that controls the switching unit 110 illustrated in FIG. 1. The pulse “VVDD” represents the variable voltage signal outputted by the power supply circuit 120, and the pulse “Y” represents a summed pulse representation of the combination of the CS and the VVDD pulses.

At time point “t1”, the first control signal CS transitions from a high level to a low level and transmission of the input signal IN to the first output terminal OUT1 is interrupted. Therefore OUT1 does not receive the IN signal. At a time point “t2” until time “t3,” the variable voltage VVDD changes from the first voltage VDD1 to the second voltage VDD2, but the control signal CS remains at a low level and the transmission of the input signal IN remains interrupted. At a time point “t3”, the variable voltage VVDD changes from the second voltage VDD2 to the first voltage VDD1, CS remains low and the transmission of the input signal IN remains interrupted. At a time point “t4”, the first control signal CS transitions to the high level and the input signal IN is transmitted to the first output terminal OUT1. Then, the latch circuit 130 shifts the voltage of the first output terminal OUT1 to the level of the first voltage VDD1 in response to the input signal IN at a high level CS and the first voltage VDD1.

At a time point “t5”, the first control signal CS transits to the low level. So, the transmission of the input signal IN to the first output terminal OUT1 is interrupted and the variable voltage VVDD changes from the first voltage VDD1 to the second voltage VDD2. In a period from the time point “t5” to a time point “t6”, the latch circuit 130 shifts the voltage of the first output terminal OUT1 from the first voltage VDD1 to the second voltage VDD2 in response to the variable voltage VVDD.

At the time point “t6”, because the first control signal CS remains at a low level, the input signal IN is not transmitted to the first output terminal OUT1 and the latch circuit 130 shifts the voltage of the first output terminal OUT1 to the first voltage VDD1 in response to the first voltage VDD1 because CS remains low. At a time point “t7”, the first control signal CS transitions to the high level and the input signal IN is transmitted at a low level to the first output terminal OUT1. Then, the latch circuit 130 shifts the voltage of the first output terminal OUT1 to the ground voltage VSS in response to the input signal IN at the low level. Referring to FIG. 5, the transition periods of the first control signal CS and the variable voltage VVDD do not overlap each other.

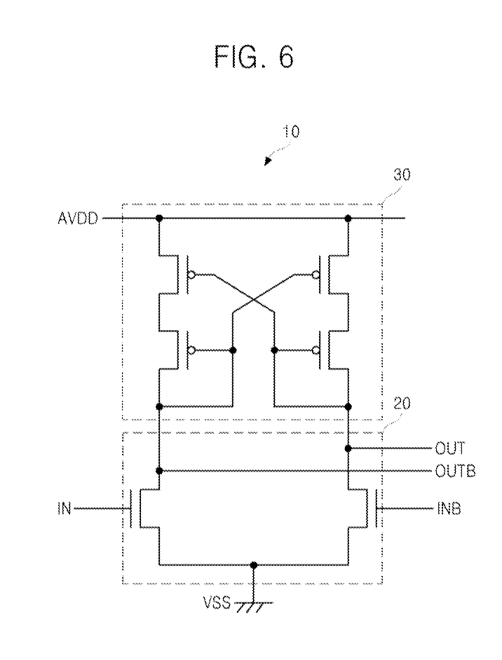

FIG. 6 is a circuit diagram of a level shifter 10 illustrated for comparison with the level shifter 100 according to embodiments of the present general inventive concept. Referring to FIG. 6, the level shifter 10 is connected between a fixed power supply line AVDD and a ground voltage line VSS and includes a transistor pair 20 receiving differential input signals IN and INB and a load terminal 30 having a diode structure.

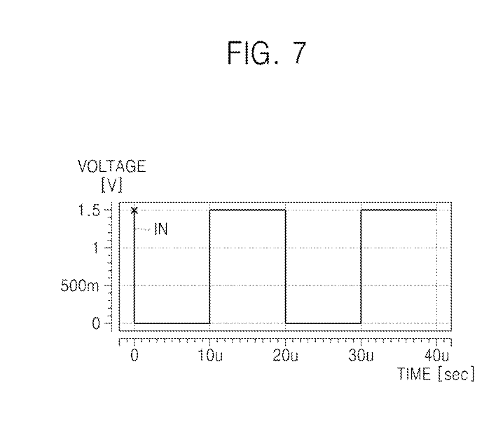

FIGS. 7 through 9B are graphs illustrating a comparison of results of simulating the level shifter 10 illustrated in FIG. 6 with results of simulating the level shifter 100 according to embodiments of the present general inventive concept. Simulation conditions are as follows: a load was set to be a 1 pF capacitor; the level shifter 10 used a fixed voltage of 6 V as a driving voltage; and the level shifter 100 used a variable voltage including the second voltage VDD2 of 6 V as a driving voltage.

FIG. 7 is a graph of the input signal IN of the level shifters 10 and 100. Referring to FIG. 7, the input signal IN is a digital signal having a minimum voltage of 0 V and a maximum voltage of 1.5 V.

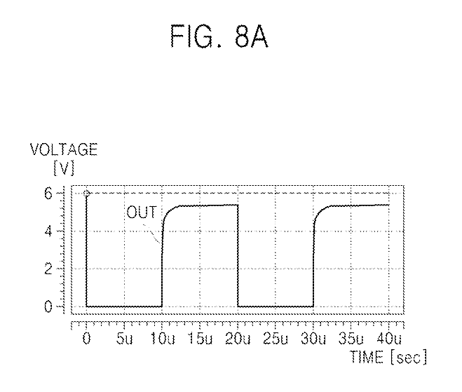

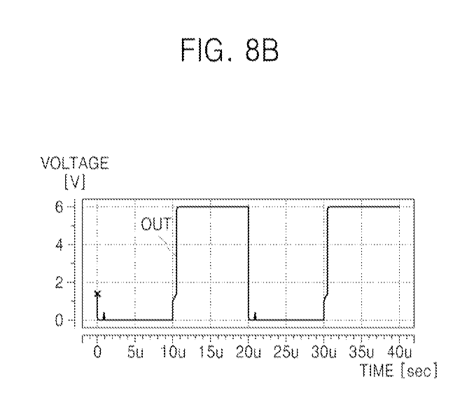

FIG. 8A is a graph of the voltage of a first output terminal OUT of the level shifter 10 illustrated in FIG. 6. FIG. 8B is a graph of the voltage of the first output terminal OUT1 of the level shifter 100 according to embodiments of the present general inventive concept. Referring to FIG. 8A, an output voltage of the level shifter 10 does not reach 6 V because of a voltage drop caused by the diode structure of the load terminal 30, but an output voltage of the level shifter 100 illustrated in FIG. 8B reaches 6 V.

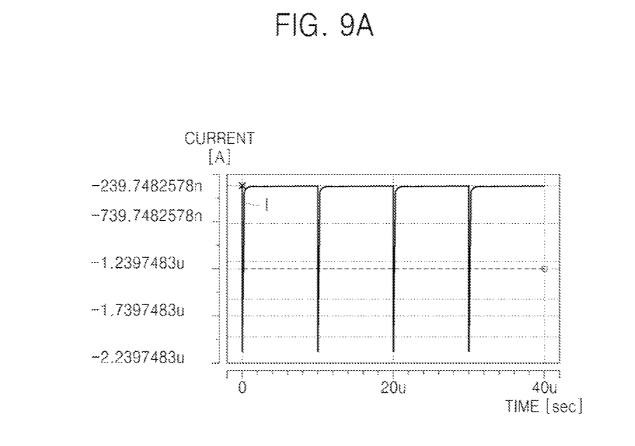

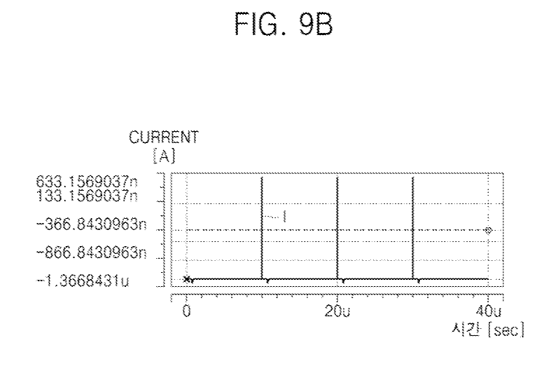

FIG. 9A is a graph of a current I supplied from a fixed power supply AVDD of the level shifter 10 illustrated in FIG. 6. FIG. 9B is a graph of a current I supplied from the power supply circuit 120 of the level shifter 100 according to embodiments of the present general inventive concept. Referring to FIG. 9A, the current I of the level shifter 10 averages about 1.24 μA as seen by the dotted line, but the current of the level shifter 100 illustrated in FIG. 9B averages about 0.37 μA, which means that the level shifter 100 consumes less electric power than the level shifter 10 under the same load condition.

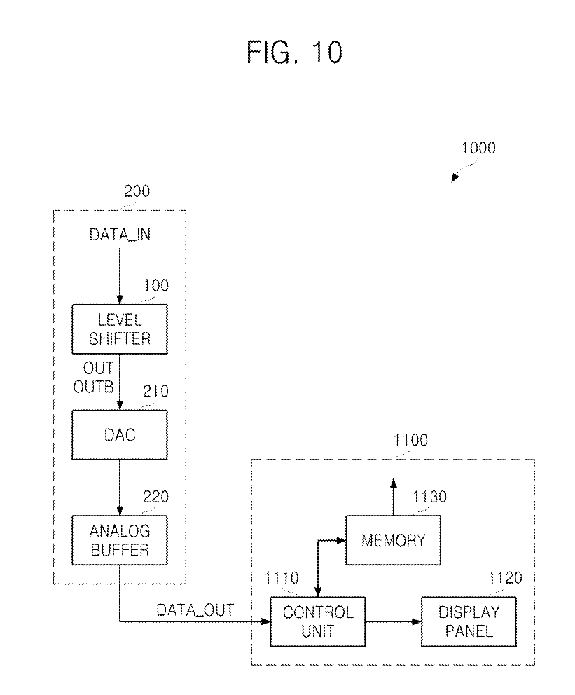

FIG. 10 is a block diagram of a driving circuit 200 of a display device 1000 according to embodiments of the present general inventive concept. The display device 1000 may include the driving circuit 200 and a display unit 1100. Referring to FIG. 10, the driving circuit 200 may include the level shifter 100, a digital-to-analog converter (DAC) 210, and an analog buffer 220.

The level shifter 100 may receive digital data DATA_IN output from a timing controller (not illustrated) and perform level shifting on the digital data DATA_IN. The detailed operations of the level shifter 100 have been described with reference to FIGS. 1 through 9B. Thus, descriptions thereof will be omitted.

The DAC 210 may receive level-shifted digital data from either or both level shifter outputs OUT and OUTB and convert the level-shifted digital data into an analog voltage (or a gray-scale voltage) DATA_OUT. The analog buffer 220 may buffer the analog voltage DATA_OUT. The DATA_OUT may then be transmitted to a control unit 1110 which is responsible for the operation of a display device 1000, as well as the above described method and apparatus of controlling the operation of the level shifter 100 including the power supply circuit 120. The control unit may include an internal or external memory 1130 to store program data as well as program inputs and outputs to be used to control the time controller and other elements of the display device.

A display panel 1120 may be driven with the analog voltage DATA_OUT which may be processed by the control unit 1110. The display panel may be any one of flat panels including liquid crystal display (LCD) panels, plasma display panels (PDPs), an organic electroluminescent display (OELD) panels.

It is possible that the control unit 1110 is included in the display panel 1120. It is also possible that the DATA_OUT is transmitted directly to the display panel 1120 in the standby mode according to DATA_OUT. In this case, the control unit 1110 may perform the overall operations of the display device 1000 and video data from the memory 1130 can be directed to the display panel to form an image in an operation mode.

As described above, according to the present general inventive concept, a level shifter and a driving circuit including the same use a latch circuit driven with a variable voltage, thereby decreasing the size and the power consumption of a display device.

Although a few embodiments of the present general inventive concept have been illustrated and described, it will be appreciated by those skilled in the art that changes may be made in these embodiments without departing from the principles and spirit of the general inventive concept, the scope of which is defined in the appended claims and their equivalents.

What is claimed is:

1. A level shifter comprising:
a switching unit configured to selectively output an input signal to a first output terminal in response to a first control signal;
a power supply circuit configured to generate a variable voltage signal, which changes when level shifting is performed, in response to a plurality of second control signals; and
a latch circuit configured to perform the level shifting in response to input signals selectively output by the switching unit and the variable voltage signal,
wherein transition periods of the first control signal and the variable voltage signal do not overlap each other.

2. The level shifter of claim 1, wherein the latch circuit comprises a pair of inverters connected in parallel between the first output terminal and a second output terminal in opposite directions, the inverters respectively configured to be operated based on the variable voltage signal and a third voltage.

3. The level shifter of claim 2, wherein the power supply circuit comprises:
a plurality of voltage input terminals configured to respectively receive voltages having different levels; and
a plurality of switches each configured to selectively connect a corresponding terminal among the plurality of voltage input terminals to a variable voltage output terminal in response to a corresponding signal among the plurality of second control signals.

4. The level shifter of claim 3, wherein transition periods of the second control signals do not overlap each other.

5. The level shifter of claim 4, wherein the plurality of switches comprise:
a plurality of first switches connected in series between a first input terminal receiving a first voltage and the variable voltage output terminal and configured to operate in response to a corresponding signal among the plurality of second control signals; and
at least one second switch connected between a second input terminal receiving a second voltage and the variable voltage output terminal and configured to operate in response to a corresponding signal among the plurality of second control signals.

6. The level shifter of claim 4, wherein the power supply circuit comprises a discharge circuit connected between a ground voltage line and a first node between a first input terminal receiving a first voltage and the variable voltage output terminal, the discharge circuit decreasing a voltage of the first node down to a predetermined voltage level in response to a third control signal while the variable voltage signal is transitioning from a second level higher than a first level to the first level.

7. The level shifter of claim 6, wherein the discharge circuit comprises:
a control element connected between the first node and a second node to determine whether to drive the discharge circuit in response to the third control signal; and
at least one transistor connected between the second node and the ground voltage line in diode connection.

8. The level shifter of claim 4, wherein the power supply circuit comprises a stabilizing circuit connected between the variable voltage output terminal and a ground voltage line to prevent rapid change of the variable voltage signal.

9. The level shifter of claim 8, wherein the stabilizing circuit comprises a capacitor connected between the variable voltage output terminal and the ground voltage line.

10. A driving circuit in a display device, the driving circuit comprising:
a level shifter configured to receive digital data and perform level shifting on the digital data;
a digital-to-analog converter configured to receive level-shifted digital data and convert the level-shifted digital data into an analog voltage; and
an analog buffer configured to buffer the analog voltage to a display panel,
wherein the level shifter comprises:
a switching unit configured to selectively output an input signal to a first output terminal in response to a first control signal;
a power supply circuit configured to generate a variable voltage signal, which changes when level shifting is performed, in response to a plurality of second control signals; and
a latch circuit configured to perform the level shifting in response to input signals selectively output by the switching unit and the variable voltage signal, and
wherein transition periods of the first control signal and the variable voltage signal do not overlap each other.

11. The driving circuit of claim 10, wherein the latch circuit comprises a pair of inverters connected in parallel between the first output terminal and a second output terminal in opposite directions, the inverters respectively configured to be operated based on the variable voltage signal and a third voltage.

12. The driving circuit of claim 11, wherein the power supply circuit comprises:
a plurality of voltage input terminals configured to respectively receive voltages having different levels; and
a plurality of switches each configured to selectively connect a corresponding terminal among the plurality of voltage input terminals to a variable voltage output terminal in response to a corresponding signal among the plurality of second control signals.

13. The driving circuit of claim 11, wherein transition periods of the second control signals do not overlap each other.

14. The driving circuit of claim 13, wherein the plurality of switches comprise:
a plurality of first switches connected in series between a first input terminal receiving a first voltage and the variable voltage output and configured to operate in response to a corresponding signal among the plurality of second control signals; and
at least one second switch connected between a second input terminal receiving a second voltage and the variable voltage output terminal and configured to operate in response to a corresponding signal among the plurality of second control signals.

15. The driving circuit of claim 13, wherein the power supply circuit comprises a discharge circuit connected between a ground voltage line and a first node between a first input terminal receiving a first voltage and the variable voltage output terminal, the discharge circuit decreasing a voltage of the first node down to a predetermined voltage level in response to a third control signal while the variable voltage signal is transitioning from a second level higher than a first level to the first level.

16. The driving circuit of claim 15, wherein the discharge circuit comprises:
a control element connected between the first node and a second node to determine whether to drive the discharge circuit in response to the third control signal; and
at least one transistor connected between the second node and the ground voltage line in diode connection.

17. The driving circuit of claim 13, wherein the power supply circuit comprises a stabilizing circuit connected between the variable voltage output terminal and a ground voltage line to prevent rapid change of the variable voltage signal.

18. The driving circuit of claim 13, wherein the stabilizing circuit comprises a capacitor connected between the variable voltage output terminal and the ground voltage line.

19. A display device comprising:
a display unit;
a level shifter configured to receive digital data and perform level shifting on the digital data, and to output the level shifted data to the display unit such that the display unit displays an image according to the level shifted data;
wherein the level shifter comprises
a switching unit configured to selectively output an input signal to a first output terminal in response to a first control signal;
a power supply circuit configured to generate a variable voltage signal, which changes when level shifting is performed, in response to a plurality of second control signals; and
a latch circuit configured to perform the level shifting in response to input signals selectively output by the switching unit and the variable voltage signal,
wherein transition periods of the first control signal and the variable voltage signal do not overlap each other.

20. A level shifter in a display device comprising:
a switching unit to selectively transmit an input signal according to a first control signal; and
a latch circuit unit to adjust a level of the input signal according to a variable voltage signal,
wherein transition periods of the first control signal and the variable voltage signal do not overlap.
